(19) United States
(12) Patent Application Publication
(10) Pub. No.: US 2023/0154928 A1
(43) Pub. Date: May 18, 2023

(54) ARRAY SUBSTRATE, MANUFACTURING METHOD THEREOF, DISPLAY PANEL AND DISPLAY DEVICE

(71) Applicants: Beijing BOE Display Technology Co., Ltd., Beijing (CN); BOE TECHNOLOGY GROUP CO., LTD., Beijing (CN)

(72) Inventors: Wei CAO, Beijing (CN); Xiaona LIU, Beijing (CN); Yu MA, Beijing (CN); Tingting WANG, Beijing (CN)

(21) Appl. No.: 17/622,132

(22) PCT Filed: Feb. 26, 2021
(86) PCT No.: PCT/CN2021/078166

§ 371 Date: Dec. 22, 2021

(51) Int. Cl. H01L 27/12; G02F 1/1362; G02F 1/1368

(52) U.S. Cl. CPC H01L 27/1218; G02F 1/136295; H01L 27/124; G02F 1/1368; G02F 1/136222; H01L 27/1262

(57) ABSTRACT

An array substrate includes a first base substrate, an insulating layer group, a second electrode, a transparent conductive layer, and a first electrode; the transparent conductive layer and the first electrode are laminated and formed on the same side of the first base substrate; the first electrode has a first opening; the insulating layer group is arranged on a side of the first electrode or the transparent conductive layer away from the first base substrate; the second electrode is arranged on a side of the insulating layer group away from the first base substrate, the second electrode is arranged opposite to the first opening.

### TECHNICAL FIELD

The disclosure relates to the field of display technology, and in particular to an array substrate, a method for manufacturing the array substrate, a display panel including the array substrate, and a display device including the display panel.

### BACKGROUND

As industry's energy consumption standards continue to upgrade, a terminal market's demand for a displayer with high performance and low power consumption is gradually increasing. Achieving low power consumption not only requires the displayer to have a high aperture ratio to achieve a high transmittance, but also requires that the transmittance is less affected by a manufacturing process.

At present, a pixel design of a twisted nematic (TN) product requires higher accuracy of cell alignment. As long as there is a deviation in the cell alignment, the aperture ratio may be lost, which may greatly affect the transmittance of the product and affect the energy consumption of the terminal product; and a rubbing shadow area may be generated, which may affect the arrangement of liquid crystals and cause light leakage, thereby affecting the display quality of the product.

It should be noted that the information disclosed in the background section above is only used to enhance the understanding of the background of the disclosure, and therefore may include information that does not constitute the prior art known to those of ordinary skill in the art.

### SUMMARY

The purpose of the disclosure is to overcome the above-mentioned shortcomings of the prior art, and provide an array substrate, a method for manufacturing the array substrate, a display panel including the array substrate, and a display device including the display panel.

According to an aspect of the disclosure, there is provided an array substrate, including:

a first base substrate;

a transparent conductive layer and a first electrode, laminated and formed on the same side of the first base substrate, the first electrode having a first opening, and the orthographic projection of the first electrode on the first base substrate being located within the orthographic projection of a black matrix on the first base substrate;

an insulating layer group, arranged on a side of the first electrode or the transparent conductive layer away from the first base substrate; and

a second electrode, arranged on a side of the insulating layer group away from the first base substrate, the second electrode being arranged opposite to the first opening, and the orthographic projection of the second electrode on the first base substrate partially overlaps with the orthographic projection of the transparent conductive layer on the first base substrate.

In some exemplary embodiments of the disclosure, the transparent conductive layer is disposed between the first electrode and the first base substrate.

In some exemplary embodiments of the disclosure, the first electrode is disposed between the transparent conductive layer and the first base substrate.

In some exemplary embodiments of the disclosure, the orthographic projection of the first electrode on the first base substrate is located within the orthographic projection of the transparent conductive layer on the first base substrate, or the orthographic projection of the first electrode on the first base substrate partially overlaps with the orthographic projection of the transparent conductive layer on the first base substrate.

In some exemplary embodiments of the disclosure, the array substrate further includes:

a thin film transistor, a gate line, a data line and a common electrode line, the thin film transistor including a source electrode, a drain electrode and a gate electrode;

wherein the source electrode and the drain electrode are formed in the same layer and with the same material as the data line, the source electrode is electrically connected to the data line, and the drain electrode is electrically connected to the second electrode; and

the first electrode, the gate line, and the common electrode line are formed in the same layer and with the same material as the gate electrode, and the gate line is electrically connected to the gate electrode and the common electrode line is electrically connected to the first electrode.

In some exemplary embodiments of the disclosure, the array substrate further includes:

a first auxiliary wire formed in the same layer and with the same material as the transparent conductive layer, and the orthographic projection of the gate line on the first base substrate being at least partially overlapped with the orthographic projection of the first auxiliary wire on the first base substrate.

In some exemplary embodiments of the disclosure, the array substrate further includes:

a second auxiliary wire formed in the same layer and with the same material as the transparent conductive layer, and the orthographic projection of the common electrode line on the first base substrate being at least partially overlapped with the orthographic projection of the second auxiliary wire on the first base substrate.

In some exemplary embodiments of the disclosure, a common electrode includes the first electrode and the transparent conductive layer which are stacked, and the second electrode is a pixel electrode.

In some exemplary embodiments of the disclosure, the material of the transparent conductive layer is Indium Tin Oxide (ITO) and the material of the second electrode is ITO.

According to another aspect of the disclosure, there is provided a method for manufacturing an array substrate, including:

providing a first base substrate;

forming a transparent conductive layer and a first electrode laminated on a side of the first base substrate, the first electrode having a first opening, and the orthographic projection of the first electrode on the first base substrate being located within the orthographic projection of a black matrix on the first base substrate;

forming an insulating layer group on a side of the first electrode or the transparent conductive layer away from the first base substrate; and

forming a second electrode on a side of the insulating layer group away from the first base substrate, wherein the second electrode is arranged opposite to the first opening, and the orthographic projection of the second electrode on the first base substrate partially overlaps with the orthographic projection of the transparent conductive layer on the first base substrate.

In some exemplary embodiments of the disclosure, the forming the transparent conductive layer and the first electrode, which are laminated on the side of the first base substrate includes:

sequentially forming a transparent conductive material layer and a first electrode material layer on the side of the first base substrate; and

sequentially forming the first electrode and the transparent conductive layer through twice of etching after exposure with the same mask.

In some exemplary embodiments of the disclosure, a gate line, a common electrode line and a gate electrode are formed at the same time as the first electrode is formed.

In some exemplary embodiments of the disclosure, a first auxiliary wire and a second auxiliary wire are formed at the same time as the transparent conductive layer is formed, the orthographic projection of the gate line on the first base substrate is at least partially overlapped with the orthographic projection of the first auxiliary wire on the first base substrate, and the orthographic projection of the common electrode line on the first base substrate is at least partially overlapped with the orthographic projection of the second auxiliary wire on the first base substrate.

According to further another aspect of the disclosure, there is provided a display panel, including:

the array substrate according to any one of the embodiment as described above;

a color filter substrate arranged opposite to the array substrate, the color filter substrate including a second base substrate, and a black matrix and a color filter layer arranged in an array form on a side of the second base substrate close to the array substrate; and

a sealant frame bonded between the array substrate and the sealant frame.

According to yet another aspect of the disclosure, there is provided a display device including the above display panel.

In the array substrate and the method for manufacturing the array substrate according to the disclosure, the orthographic projection of the first electrode on the first base substrate is located within the orthographic projection of the black matrix on the first base substrate, such that an edge of the first electrode is located within an edge of the black matrix. During a cell alignment, even if there is a slight deviation, the aperture ratio may not be lost, the transmittance of the product may not be affected, and the energy consumption of the terminal product may not be affected. Moreover, the orthographic projection of the second electrode on the first base substrate partially overlaps with the orthographic projection of the transparent conductive layer on the first base substrate, and the second electrode and the transparent conductive layer may form a storage capacitor. Since the transparent conductive layer transmits light, the overlapping area of the second electrode and the transparent conductive layer can be made larger than the overlapping area of the first electrode and the second electrode in the prior art. In addition, because the first electrode is thinner than that made in the prior art and a rubbing shadow area caused by the height difference between the first electrode and the second electrode is blocked by the black matrix, the product quality is improved.

It should be understood that the above general description and the following detailed description are only exemplary and explanatory, and cannot limit the disclosure.

### BRIEF DESCRIPTION OF THE DRAWINGS

The drawings herein, which are incorporated in and constitute a part of the specification, illustrate embodiments consistent with the disclosure, and serve to explain the principles of the disclosure together with the description. Obviously, the drawings in the following description are just some embodiments of the disclosure. For those of ordinary skill in the art, other drawings may be obtained based on these drawings without creative efforts.

FIG. 1 is a schematic structural diagram of a display panel in the related art, which is cut according to a cutting line perpendicular to a data line.

FIG. 2 is a schematic structural diagram of a display panel in the related art, which is cut according to a cutting line perpendicular to a gate line.

FIG. 3 is a schematic structural diagram of an exemplary embodiment of an array substrate according to the disclosure.

FIG. 4 is a schematic structural diagram of the array substrate in FIG. 3 cut according to a cutting line perpendicular to a data line.

FIG. 5 is a schematic structural diagram of the array substrate in FIG. 3 cut according to a cutting line perpendicular to a gate line.

FIG. 6 is a schematic flow chart of an exemplary embodiment of a method for manufacturing an array substrate according to the disclosure.

FIG. 7 is a schematic flow chart of an exemplary embodiment of a method for manufacturing an array substrate according to the disclosure.

FIGS. 8-12 are schematic structural diagrams of each step of a method for manufacturing an array substrate according to the disclosure.

FIG. 13 is a schematic structural diagram of an exemplary embodiment of a display panel according to the disclosure.

### DESCRIPTION OF REFERENCE NUMERALS

1. first base substrate;
2. common electrode; 21, transparent conductive layer; 22, first auxiliary wire; 23, second auxiliary wire;
31. first electrode; 32. gate line; 33. common electrode line;
4. gate insulation layer;
51. data line; 52. source electrode; 53, drain electrode;
6. protective layer; 7. second electrode; and
8. color film substrate; 81, second base substrate; 82, black matrix; 83, color film layer.

### DETAILED DESCRIPTION

Example embodiments will now be described more fully with reference to the accompanying drawings. However, the example embodiments can be implemented in various forms and should not be construed as limited to the embodiments set forth herein; rather, these embodiments are provided so that this disclosure will be thorough and complete, and will fully convey the concept of the example embodiments to those skilled in the art. The same reference numerals in the drawings denote the same or similar structures, and thus their detailed descriptions will be omitted. In addition, the drawings are merely schematic illustrations of the disclosure and are not necessarily drawn to scale.

Although relative terms such as “above” and “below” are used in this specification to describe the relative relationship between one component illustrated in the drawings and another component, these terms are used in this specification for convenience only, for example, according to the illustrative direction depicted in the drawings. It can be understood that if the device illustrated in the drawings is inversed and turned upside down, the component described “above” would become the component “below”. When a structure is “on” other structure(s), it may mean that the structure is integrally formed on the other structure(s), or that the structure is “directly” arranged on the other structure(s), or that the structure is “indirectly” arranged on other structure(s) through another structure.

The terms “a”, “an”, “the”, “said” and “at least one” are used to indicate the presence of one or more elements/components/etc.; the terms “comprising” and “including” are used to indicate open-ended inclusive means, and means that there may be additional elements/components/etc., in addition to the listed elements/components/etc.; and the terms such as “first”, “second” and “third” and are only used as markers, not to limit the number of objects.

In a twisted nematic (TN) display mode liquid crystal display panel, a first polarizer is disposed on a lower side of a thin film transistor (TFT) substrate, a second polarizer is disposed on an upper side of a color film substrate 8, and light transmission directions of the first polarizer and the second polarizer are perpendicular to each other. If no external electric field is applied to a liquid crystal cell, since the twisted pitch of liquid crystal molecules in the cell in the TN liquid crystal screen is much larger than the wavelength of visible light, when a polarization direction of incident ray polarized light is consistent with an arrangement direction of liquid crystal molecules on a glass surface, its polarization direction is twisted by 90° as the liquid crystal molecules are twisted and deformed after passing through the entire liquid crystal layer to be emitted from the other side, so as to present a light-transmitting state. If a voltage is applied to the liquid crystal cell and reaches a certain value at this time, the long axis of the liquid crystal molecules may start to tilt along a direction of the electric field. Except for the liquid crystal molecules on the surfaces of the electrodes, all the liquid crystal molecules between the two electrodes in the liquid crystal cell become rearranged along the direction of the electric field. At this time, the 90° optical rotation function disappears, and the optical rotation function is lost between the orthogonal polarizers, making the device unable to transmit light.

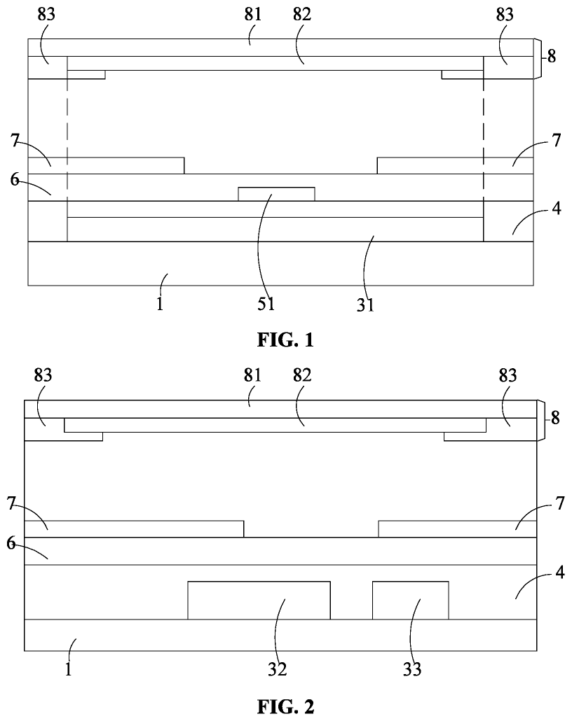

Referring to structural schematic diagrams of the display panel in the related art shown in FIGS. 1 and 2, in order to improve the transmittance of the product, a black matrix (BM) 82 and a common electrode 2 are designed to be edge-aligned with each other to maximize the aperture ratio. At the same time, in order to ensure the storage capacitance of the product, the common electrode 2 and a pixel electrode (i.e., a second electrode 7) overlap to a certain extent and the common electrode 2 is formed by exposing a gate metal layer. Since the common electrode 2 is not light-transmitted, and edge-aligned with the black matrix 82, as long as there is a deviation in the accuracy of cell alignment during the manufacturing process, the aperture ratio may be lost, which may greatly affect the transmittance of the product and affect the energy consumption of the terminal product.

At the same time, because the black matrix 82 is edge-aligned with the common electrode 2, height difference between the common electrode 2 and the pixel electrode (i.e., the second electrode 7) may make a rubbing film located above uneven, such that a rubbing shadow area is occurred during a rubbing process, which may affect the arrangement of liquid crystals and cause light leakage, thereby affecting the display quality of the product. The area corresponding to the rubbing shadow area is not subjected to rubbing alignment treatment or the rubbing alignment treatment is different from other areas, resulting in disorder of the liquid crystal orientation in the rubbing shadow area, so that in the dark state light leakage problem of the liquid crystal display panel is generated and the contrast of the liquid crystal display panel is reduced.

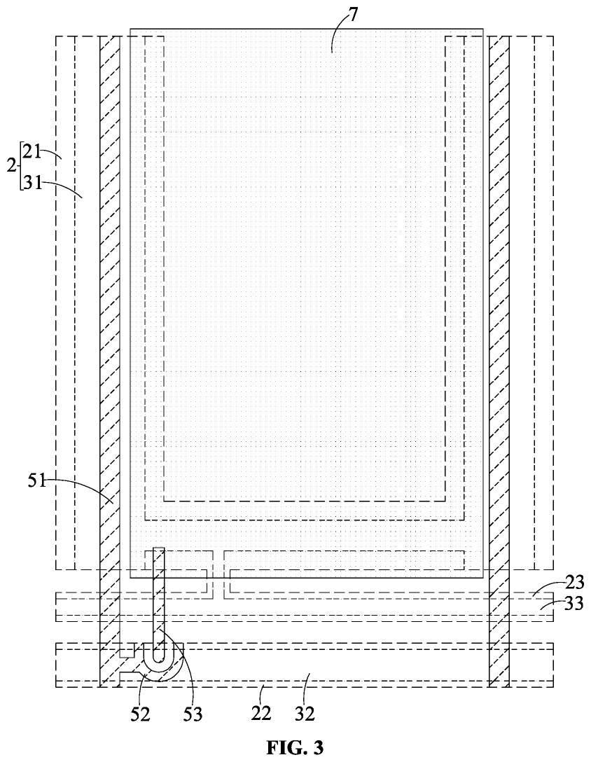

An example embodiment of the disclosure provides an array substrate. As shown in FIGS. 3-6, which is respectively a schematic structural diagram of an exemplary embodiment of an array substrate according to the disclosure, the array substrate may include a first base substrate 1, an insulating layer group, a second electrode 7, a transparent conductive layer 21, and a first electrode 31; the transparent conductive layer 21 and the first electrode 31, which are laminated and formed on the same side of the first base substrate 1; the first electrode 31 has a first opening, and the orthographic projection of the first electrode 31 on the first base substrate 1 is located within the orthographic projection of a black matrix 82 on the first base substrate 1; the insulating layer group is arranged on a side of the first electrode 31 or the transparent conductive layer 21 away from the first base substrate 1; and the second electrode 7 is arranged on a side of the insulating layer group away from the first base substrate 1, the second electrode 7 is arranged opposite to the first opening, and the orthographic projection of the second electrode 7 on the first base substrate 1 partially overlaps with the orthographic projection of the transparent conductive layer 21 on the first base substrate 1.

In the array substrate and a method for manufacturing the array substrate according to the disclosure, the orthographic projection of the first electrode 31 on the first base substrate 1 is located within the orthographic projection of the black matrix 82 on the first base substrate 1, such that an edge of the first electrode 31 is located within an edge of the black matrix 82. During the cell alignment, even if there is a slight deviation, the aperture ratio may not be lost, the transmittance of the product may not be affected, and the energy consumption of the terminal product may not be affected. Moreover, the orthographic projection of the second electrode 7 on the first base substrate 1 partially overlaps with the orthographic projection of the transparent conductive layer 21 on the first base substrate 1, and the second electrode 7 and the transparent conductive layer 21 may form a storage capacitor. Since the transparent conductive layer 21 transmits light, the overlapping area of the second electrode 7 and the transparent conductive layer 21 can be made larger than the overlapping area of the first electrode 31 and the second electrode 7 in the prior art. In addition, because the first electrode 31 is thinner than that made in the prior art and the rubbing shadow area caused by the height difference between the first electrode 31 and the second electrode 7 is blocked by the black matrix, the product quality is improved.

Referring to Table 1, a comparison table of accuracy of cell alignment and transmittance in the related art and the disclosure is showed.

TABLE 1

| | accuracy of cell alignment | | | | |
|---|---|---|---|---|---|
| | 0 μm | 1 μm | 2 μm | 3 μm | 4 μm |
| transmittance of | 100% | 98.6% | 96.8% | 94.9% | 93% |
| the related art | | | | | |
| transmittance of | 100% | 100% | 99.7% | 98.0% | 96.3% |
| the disclosure | | | | | |

It can be obtained from Table 1 that: when the accuracy of cell alignment is about 1 μm, the transmittance of the disclosure can still reach 100%, while the transmittance in the related art drops to about 98.6%; when the accuracy of cell alignment is about 2 μm, the transmittance of the disclosure can still reach about 99.7%, while the transmittance in the related art drops to about 96.8%; when the accuracy of cell alignment is about 3 μm, the transmittance of the disclosure can still reach about 98.0%, while the transmittance in the related art in the related art drops to about 94.9%; when the accuracy of cell alignment is about 4 μm, the transmittance of the disclosure can still reach about 96.3%, while the transmittance in the related art in the related art drops to about 93%. Therefore, under the condition of ensuring the same transmittance, the accuracy of cell alignment may be reduced, thereby improving production efficiency and reducing the production cost.

In the example embodiment, the first base substrate 1 may be a glass substrate, or may also be a plastic substrate, a resin substrate, and the like.

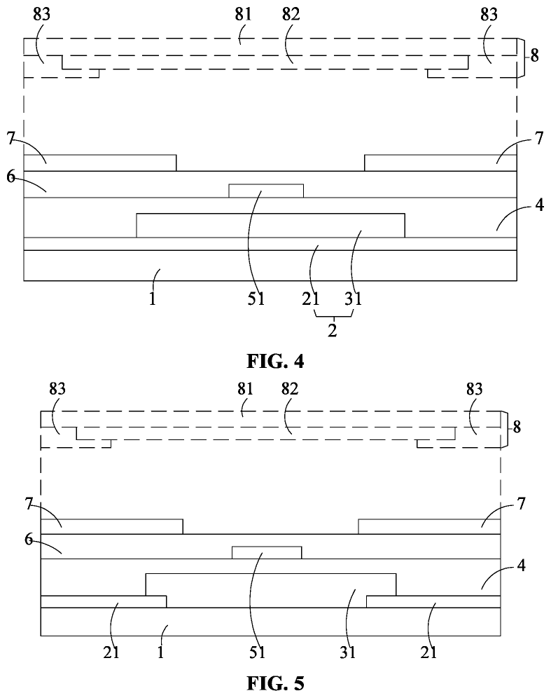

Referring to FIG. 4, a barrier layer and a buffer layer (not shown in the drawing) are sequentially provided on a side of the first base substrate 1. The transparent conductive layer 21 is provided on a side of the buffer layer away from the first base substrate 1. The transparent conductive layer 21 may include a first conductive strip, a second conductive strip, and a third conductive strip. The first conductive strip, the second conductive strip, and the third conductive strip are all arranged in a long strip shape. The transparent conductive layer 21 has a second opening. The first conductive strip and the second conductive strip are substantially parallel and have substantially the same length. The third conductive strip is located at an end of the first conductive strip and the second conductive strip, and is connected between the first conductive strip and the second conductive strip to form a “U” shape.

The material of the transparent conductive layer 21 may be Indium Tin Oxide (ITO), zinc oxide, aluminum doped zinc oxide (AZO), and the like.

The first electrode 31 is provided on a side of the transparent conductive layer 21 away from the first base substrate 1. The transparent conductive layer 21 and the first electrode 31 jointly form a common electrode 2. The first electrode 31 has the first opening, and the second opening is disposed opposite to the first opening. The first electrode 31 includes a first metal strip, a second metal strip and a third metal strip, and the first metal strip, the second metal strip and the third metal strip are all arranged in a long strip shape. The first metal strip and the second metal strip are substantially parallel and have substantially the same length. The third metal strip is located at an end of the first metal strip and the second metal strip, and is connected between the first metal strip and the second metal strip to form a “U” shape.

The material of the first electrode 31 may be a metal material such as Ni, Au, Pt, Al, etc., and the first electrode 31 is an opaque conductive material.

The orthographic projection of the first electrode 31 on the base substrate is within the orthographic projection of the transparent conductive layer 21 on the base substrate. That is, the shape of the first electrode 31 is substantially the same as the shape of the transparent conductive layer 21, and the area of the first electrode 31 is smaller than the area of the transparent conductive layer 21.

Of course, the structure of the transparent conductive layer 21 is not limited to the above description. For example, the transparent conductive layer 21 may only include the first conductive strip and the second conductive strip, but may not include the third conductive strip. The main purpose of the transparent conductive layer 21 is to increase the conductive area of the first electrode 31, so that the first electrode 31 can be made thinner. Thus, with reference to FIG. 5, the transparent conductive layer 21 may be provided at the edge of the first electrode 31. In order to ensure the reliability of the connection between the first electrode 31 and the transparent conductive layer 21, the edge area of the first electrode 31 may be partially overlapped with the transparent conductive layer 21.

In addition, in other example embodiments of the disclosure, the first electrode 31 may be provided between the transparent conductive layer 21 and the first base substrate 1. That is, the first electrode 31 may be formed on the first base substrate 1, and then, the transparent conductive layer 21 is formed on the side of the first electrode 31 away from the first base substrate 1.

In the example embodiment, a gate insulating layer is provided on the side of the first electrode 31 away from the base substrate, a data line 51 is provided on a side of the gate insulating layer away from the base substrate, and a protective layer is provided on a side of the data line 51 away from the base substrate.

The second electrode 7 is disposed on a side of the protective layer away from the base substrate. The second electrode 7 may be the pixel electrode.

The material of the second electrode 7 may be a light-transmitting and conductive material such as Indium Tin Oxide (ITO), zinc oxide, aluminum doped zinc oxide (AZO), and the like.

The second electrode 7 is arranged opposite to the first opening. Of course, the second electrode 7 is arranged opposite to the second opening; and light can be emitted through the first opening, the second opening and the second electrode 7. The orthographic projection of the second electrode 7 on the first base substrate 1 partially overlaps with the orthographic projection of the transparent conductive layer 21 on the first base substrate 1. That is, the edge area of the second electrode 7 and the edge of the transparent conductive layer 21 overlap to form the storage capacitor. After the transparent conductive layer 21 and the second electrode 7 are energized, an electric field is formed to provide power for the turning of the liquid crystal molecules.

In the example embodiment, referring to FIG. 3, the array substrate may further include thin film transistors arranged in an array, gate lines 32, data lines 51, and common electrode lines 33. The thin film transistor refers to an element including at least three terminals of a gate electrode, a drain electrode 53 and a source electrode 52. The thin film transistor has a channel region (an active region) between the drain electrode 53 (a drain terminal, a drain region, or the drain electrode 53) and the source electrode 52 (a source terminal, a source region, or the source electrode 52), and current may flow through the drain electrode 53, the channel region (the active region), and the source electrode 52. The channel region refers to the region through which current mainly flows.

When using transistors with opposite polarities or when the direction of current changes during the circuit operation, the functions of the “source electrode 52” and the “drain electrode 53” may be interchanged. Therefore, in this specification, the “source electrode 52” and the “drain electrode 53” may be interchanged.

The source electrode 52 and the drain electrode 53 are formed in the same layer and with the same material as the data line 51, the source electrode 52 is electrically connected to the data line 51, and the drain electrode 53 is electrically connected to the second electrode 7.

The first electrode 31, the gate line 32, and the common electrode line 33 are formed in the same layer and with the same material as the gate electrode, and the gate line 32 is electrically connected to the gate electrode and the common electrode line 33 is electrically connected to the first electrode 31.

The so-called “formed in the same layer and with the same material” refers to the formation by the same patterning process.

Since the gate line 32 and the gate electrode are formed by the same patterning process, the connection structure may be directly formed during fabrication, and there is no need to form a connection structure separately. Of course, the gate line 32 and the gate electrode are also formed by the same patterning process, and the connection structure may be directly formed during fabrication, and there is no need to form the connection structure separately.

In the example embodiment, as shown in FIG. 6, the array substrate may further include a first auxiliary wire 22. The first auxiliary wire 22 is formed in the same layer and with the same material as the transparent conductive layer 21, and the orthographic projection of the gate line 32 on the first base substrate 1 is located within the orthographic projection of the first auxiliary wire 22 on the first base substrate 1, or the orthographic projection of the gate line 32 on the first base substrate 1 partially overlaps with the orthographic projection of the first auxiliary wire 22 on the first base substrate 1. Therefore, the gate line 32 can be made thinner, and the conductive effect of the gate line 32 can also be satisfied.

In the example embodiment, as shown in FIG. 6, the array substrate may further include a second auxiliary wire 23. The second auxiliary wire 23 is formed in the same layer and with the same material as the transparent conductive layer 21, and the orthographic projection of the common electrode line 33 on the first base substrate 1 is located within the orthographic projection of the second auxiliary wire 23 on the first base substrate 1, or the orthographic projection of the common electrode line 33 on the first base substrate 1 partially overlaps with the orthographic projection of the second auxiliary wire 23 on the first base substrate 1. Therefore, the common electrode line 33 can be made thinner, and the conductive effect of the common electrode line 33 can also be satisfied.

The second auxiliary wire 23 may be connected with the transparent conductive layer 21. Since the second auxiliary wire 23 and the transparent conductive layer 21 are formed by the same patterning process, the connection structure may be directly formed during fabrication, and there is no need to form the connection structure separately.

In addition, an example embodiment of the disclosure further provides a method for manufacturing an array substrate. With reference to a schematic flow chart of the method for manufacturing the array substrate shown in FIG. 7, the method for manufacturing the array substrate may include the following steps:

Step S10, providing a first base substrate 1;

Step S20, forming a transparent conductive layer 21 and a first electrode 31, which are laminated on a side of the first base substrate 1, the first electrode 31 having a first opening, and the orthographic projection of the first electrode 31 on the first base substrate 1 being located within the orthographic projection of a black matrix 82 on the first base substrate 1;

Step S30, forming an insulating layer group on a side of the first electrode 31 or the transparent conductive layer 21 away from the first base substrate 1; and

Step S40, forming a second electrode 7 on a side of the insulating layer group away from the first base substrate 1, arranging the second electrode 7 on the opposite to the first opening, and the orthographic projection of the second electrode 7 on the first base substrate 1 partially overlaps with the orthographic projection of the transparent conductive layer 21 on the first base substrate 1.

Each step of the method for manufacturing the array substrate will be described in detail below.

A barrier layer (not shown in the drawing) is formed on a side of the first base substrate 1, and the barrier layer is used to block the influence of moisture and impurity ions (such as excessive H+) on a subsequently formed active layer. A buffer layer (not shown in the drawing) is formed on a side of the barrier layer away from the first base substrate 1. The buffer layer functions to further block the moisture and impurity ions, and also functions to add hydrogen ions to the subsequent formed active layer. An active layer (not shown in the drawing due to the cutting position) is formed on a side of the buffer layer away from the first base substrate 1.

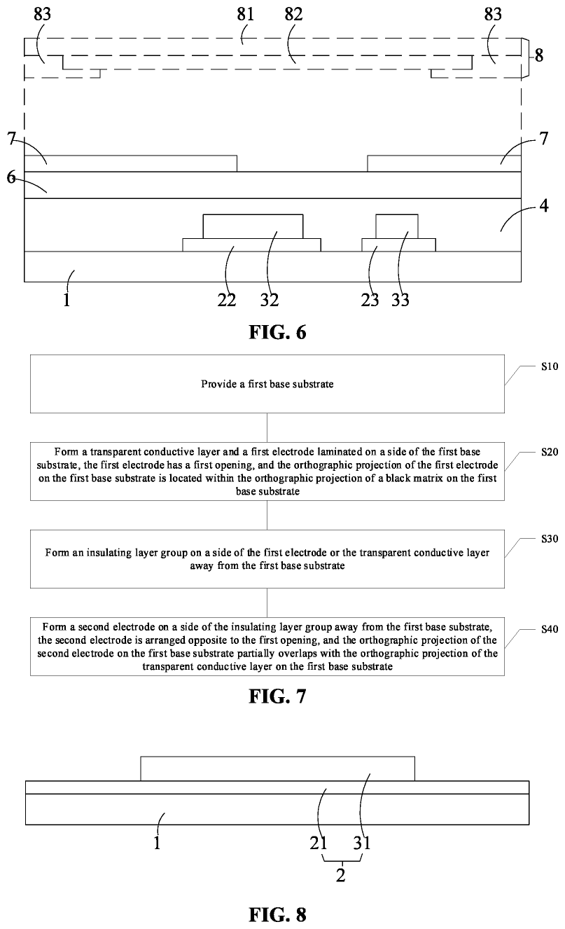

The insulating layer is formed on a side of the active layer away from the first base substrate 1. a transparent conductive material layer and a material layer of the first electrode 31 are sequentially formed on a side of the insulating layer away from the first base substrate 1; a photoresist layer is formed on the material layer of the first electrode 31, and a mask is covered on the photoresist layer. A region of the mask corresponding to a portion of the transparent conductive layer not covered by the first electrode 31 is provided as a semi-transparent mask, and then the photoresist is exposed for the first time, the photoresist that is irradiated by light (or not irradiated by light) is removed. As shown in FIG. 8, the material layer of the first electrode 31 is then etched with the photoresist as a protective layer 6 to form a gate electrode, a gate line 32, a common electrode line 33 and the first electrode 31. Then, the photoresist is exposed for a second time, and the transparent conductive material layer is etched to form the transparent conductive layer 21, a first auxiliary wire 22, and a second auxiliary wire 23. The orthographic projection of the gate line 32 on the first base substrate 1 is located within the orthographic projection of the first auxiliary wire 22 on the first base substrate 1, and the orthographic projection of the common electrode line 33 on the first base substrate 1 is located within the orthographic projection of the second auxiliary wire 23 on the first base substrate 1.

Referring to FIG. 9, a gate insulating layer 4 is formed on a side of the gate electrode, the gate line 32, the common electrode line 33 and the first electrode 31 away from the first base substrate 1. A first via hole (not shown in the drawing) is formed on the insulating layer and the gate insulating layer 4.

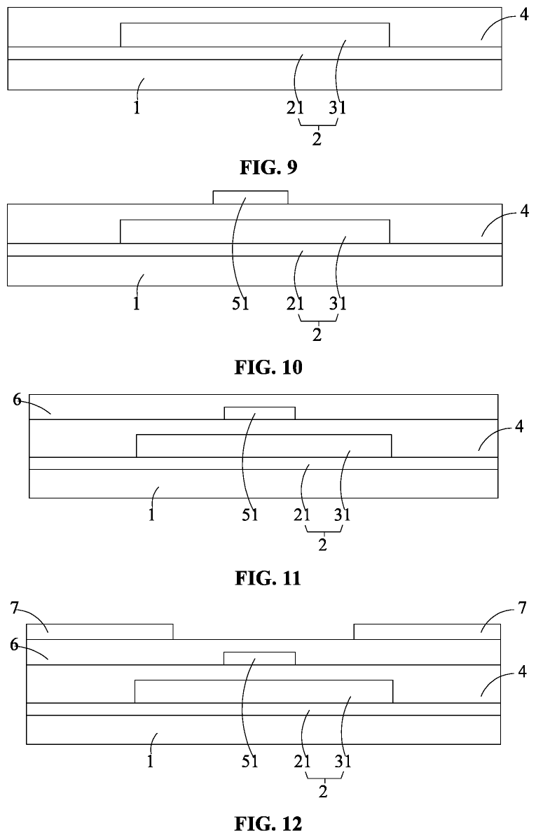

Referring to FIG. 10, a data line 51, a source electrode 52, and a drain electrode 53 (not shown in the drawing) are formed on a side of the gate insulating layer 4 away from the first base substrate 1, and the source electrode 52 and the drain electrode 53 are connected to the active layer through the first via hole.

Referring to FIG. 11, the protective layer 6 is formed on a side of the source electrode 52 and the drain electrode 53 away from the first base substrate 1. Referring to FIG. 12, the second electrode 7 is formed on a side of the protective layer 6 away from the first base substrate 1.

It should be noted that although the various steps of the method for manufacturing the array substrate in the disclosure are described in a specific order in the drawings, this does not require or imply that these steps must be performed in the specific order, or that all the steps shown must be performed to achieve the desired result. Additionally or alternatively, some steps may be omitted, a plurality of steps may be combined into one step to be executed, and/or one step may be decomposed into a plurality of steps to be executed, and the like.

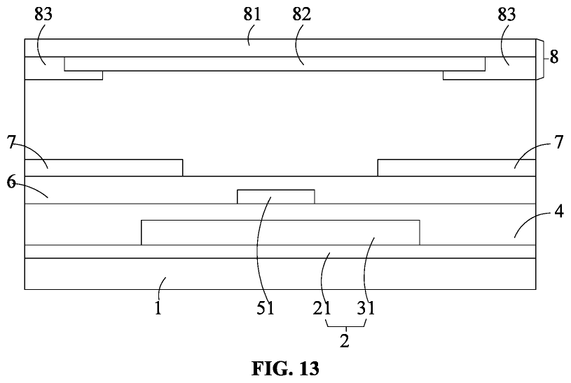

Further, an example embodiment of the disclosure also provides a display panel. As shown in FIG. 13, the display panel includes the array substrate described in any one of the above items. The specific structure of the array substrate has been described in detail above, and thus it won't be repeated herein.

The display panel further includes a color filter substrate 8 arranged opposite to the array substrate, and the color filter substrate 8 and the array substrate are bonded by a sealant frame. The color filter substrate 8 includes a second base substrate 81, and a black matrix 82 and a color filter layer 83 arranged in an array form on a side of the second base substrate 81.

Furthermore, an example embodiment of the disclosure also provides a display device, and the display device includes the display panel described in any one of the above items. The specific structure of the display panel has been described in detail above, and thus it won't be repeated herein.

The specific type of the display device is not particularly limited. The types of display devices commonly used in the field can be used, for example, a mobile device such as a mobile phone, a wearable device such as a watch, a VR device, and the like. Those skilled in the art may make a corresponding selection according to the specific purpose of the display device, and it won't be repeated herein.

It should be noted that, in addition to the display panel, the display device also includes other necessary components and portions. Take a displayer as an example, a housing, a circuit board, a power line, and the like may be included. Those skilled in the art can make corresponding supplements according to the specific usage requirements of the display device, and it won't be repeated herein.

Compared with the prior art, the beneficial effects of the display device and the display panel provided by the example embodiments of the disclosure are the same as the beneficial effects of the array substrate provided by the above-mentioned example embodiments, which won't be repeated herein.

Those skilled in the art will readily contemplate other embodiments of the disclosure after considering the specification and practicing the disclosure disclosed herein. This application is intended to cover any variations, uses, or adaptations of the disclosure that conform to the general principles of the disclosure and include the common general knowledge or conventional technical means in the technical field not disclosed by the disclosure. It is intended that the specification and embodiments be considered as exemplary only, with a true scope and spirit of the disclosure being indicated by the appended claims.

What is claimed is:

1. An array substrate, comprising:
a first base substrate;
a transparent conductive layer and a first electrode, laminated and formed on a same side of the first base substrate, wherein the first electrode is provided with a first opening, and an orthographic projection of the first electrode on the first base substrate is located within an orthographic projection of a black matrix on the first base substrate;
an insulating layer group, arranged on a side of the first electrode or the transparent conductive layer away from the first base substrate; and
a second electrode, arranged on a side of the insulating layer group away from the first base substrate, wherein the second electrode is arranged opposite to the first opening, and an orthographic projection of the second electrode on the first base substrate partially overlaps with an orthographic projection of the transparent conductive layer on the first base substrate.

2. The array substrate according to claim 1, wherein the transparent conductive layer is disposed between the first electrode and the first base substrate.

3. The array substrate according to claim 1, wherein the first electrode is disposed between the transparent conductive layer and the first base substrate.

4. The array substrate according to claim 1, wherein the orthographic projection of the first electrode on the first base substrate is located within the orthographic projection of the transparent conductive layer on the first base substrate, or the orthographic projection of the first electrode on the first base substrate partially overlaps with the orthographic projection of the transparent conductive layer on the first base substrate.

5. The array substrate according to claim 1, further comprising:
a thin film transistor, a gate line, a data line and a common electrode line, the thin film transistor comprising a source electrode, a drain electrode and a gate electrode;
wherein the source electrode and the drain electrode are formed in a same layer and with a same material as the data line, the source electrode is electrically connected to the data line, and the drain electrode is electrically connected to the second electrode; and
the first electrode, the gate line, and the common electrode line are formed in a same layer and with a same material as the gate electrode, the gate line is electrically connected to the gate electrode and the common electrode line is electrically connected to the first electrode.

6. The array substrate according to claim 5, further comprising:
a first auxiliary wire formed in a same layer and with a same material as the transparent conductive layer, wherein an orthographic projection of the gate line on the first base substrate at least partially overlaps with an orthographic projection of the first auxiliary wire on the first base substrate.

7. The array substrate according to claim 5, further comprising:
a second auxiliary wire formed in a same layer and with a same material as the transparent conductive layer, and an orthographic projection of the common electrode line on the first base substrate at least partially overlaps with an orthographic projection of the second auxiliary wire on the first base substrate.

8. The array substrate according to claim 1, wherein a common electrode comprises the first electrode and the transparent conductive layer arranged in a stacked way, and the second electrode is a pixel electrode.

9. The array substrate according to claim 1, wherein a material of the transparent conductive layer is Indium Tin Oxide (ITO) and a material of the second electrode is ITO.

10. A method for manufacturing an array substrate, comprising:
providing a first base substrate;
forming a transparent conductive layer and a first electrode laminated on a side of the first base substrate, wherein the first electrode is provided with a first opening, and an orthographic projection of the first electrode on the first base substrate is located within an orthographic projection of a black matrix on the first base substrate;
forming an insulating layer group on a side of the first electrode or the transparent conductive layer away from the first base substrate; and
forming a second electrode on a side of the insulating layer group away from the first base substrate, wherein the second electrode is arranged opposite to the first opening, and an orthographic projection of the second electrode on the first base substrate partially overlaps with an orthographic projection of the transparent conductive layer on the first base substrate.

11. The method for manufacturing the array substrate according to claim 10, wherein the forming the transparent conductive layer and the first electrode laminated on the side of the first base substrate comprises:
sequentially forming a transparent conductive material layer and a first electrode material layer on the side of the first base substrate; and
sequentially forming the first electrode and the transparent conductive layer through twice of etching after exposure with a same mask.

12. The method for manufacturing the array substrate according to claim 11, further comprising forming a gate line, a common electrode line and a gate electrode while forming the first electrode.

13. The method for manufacturing the array substrate according to claim 12, further comprising forming a first auxiliary wire and a second auxiliary wire while forming the transparent conductive layer, wherein an orthographic projection of the gate line on the first base substrate at least partially overlaps with an orthographic projection of the first auxiliary wire on the first base substrate, and an orthographic projection of the common electrode line on the first base substrate at least partially overlaps with an orthographic projection of the second auxiliary wire on the first base substrate.

14. A display panel, comprising:
an array substrate comprising:
a first base substrate;
a transparent conductive layer and a first electrode, laminated and formed on a same side of the first base substrate, wherein the first electrode is provided with a first opening, and an orthographic projection of the first electrode on the first base substrate is located within an orthographic projection of a black matrix on the first base substrate;
an insulating layer group, arranged on a side of the first electrode or the transparent conductive layer away from the first base substrate; and
a second electrode, arranged on a side of the insulating layer group away from the first base substrate, wherein the second electrode is arranged opposite to the first opening, and an orthographic projection of the second electrode on the first base substrate partially overlaps with an orthographic projection of the transparent conductive layer on the first base substrate;
a color filter substrate arranged opposite to the array substrate, wherein the color filter substrate comprises a second base substrate, and the black matrix and a color filter layer arranged in an array on a side of the second base substrate close to the array substrate; and
a sealant frame bonded between the array substrate and the color filter substrate.

15. A display device comprising the display panel according to claim 14.

16. The display panel according to claim 14, wherein the transparent conductive layer is disposed between the first electrode and the first base substrate.

17. The display panel according to claim 14, wherein the first electrode is disposed between the transparent conductive layer and the first base substrate.

18. The display panel according to claim 14, wherein the orthographic projection of the first electrode on the first base substrate is located within the orthographic projection of the transparent conductive layer on the first base substrate, or the orthographic projection of the first electrode on the first base substrate partially overlaps with the orthographic projection of the transparent conductive layer on the first base substrate.

19. The display panel according to claim 14, wherein the array substrate further comprises:
a thin film transistor, a gate line, a data line and a common electrode line, the thin film transistor comprising a source electrode, a drain electrode and a gate electrode;
wherein the source electrode and the drain electrode are formed in a same layer and with a same material as the data line, the source electrode is electrically connected to the data line, and the drain electrode is electrically connected to the second electrode; and
the first electrode, the gate line, and the common electrode line are formed in a same layer and with a same material as the gate electrode, the gate line is electrically connected to the gate electrode and the common electrode line is electrically connected to the first electrode.
